(19) United States
(12) Patent Application Publication
(10) Pub. No.: US 2025/0142959 A1
(43) Pub. Date: May 1, 2025

(54) SEMICONDUCTOR DEVICE, METHOD FOR MANUFACTURING SEMICONDUCTOR DEVICE, AND ELECTRONIC DEVICE

(71) Applicants: Yungu (Gu’an) Technology Co., Ltd., Langfang (CN); Hefei Visionox Technology Co., Ltd., Hefei (CN)

(72) Inventors: Lidong DING, Langfang (CN); Lin XU, Langfang (CN); Xiaoqi SUN, Langfang (CN); Guowen YAN, Hefei (CN); Dejian WANG, Hefei (CN); Fa-Hsyang CHEN, Langfang (CN)

(73) Assignees: Yungu (Gu’an) Technology Co., Ltd., Langfang (CN); Hefei Visionox Technology Co., Ltd., Hefei (CN)

(21) Appl. No.: 19/008,577

(22) Filed: Jan. 2, 2025

(30) Foreign Application Priority Data
Jan. 24, 2024 (CN) 202410098794.3

(51) Int. Cl. H10D 86/40; H10D 86/01

(52) U.S. Cl. CPC H10D 86/423; H10D 86/0221

(57) ABSTRACT

The present application provides a semiconductor device, a method for manufacturing a semiconductor device, and an electronic device. Two semiconductor layers having different carrier mobilities are provided, the semiconductor layer having a lower carrier mobility covers the semiconductor layer having a higher carrier mobility, and the semiconductor layer having a higher carrier mobility is located within the coverage area of a first electrode.

### CROSS REFERENCE TO RELATED APPLICATION

The present application claims priority to Chinese Patent Application No. 202410098794.3 filed on Jan. 24, 2024, which is incorporated herein by reference in its entirety.

### TECHNICAL FIELD

The present application relates to the technical field of semiconductor devices, and in particular to a semiconductor device, a method for manufacturing a semiconductor device, and an electronic device.

### BACKGROUND ART

With the development of manufacturing technology for an electronic device, there are increasingly high requirements for the size of a semiconductor device for use in the electronic device. For example, in a display panel, a semiconductor switching device having a small size and a high carrier mobility can effectively increase pixels per inch (PPI) of the display panel. However, the structure property of the current semiconductor device still needs to be improved.

### SUMMARY OF THE INVENTION

In order to overcome the above-mentioned disadvantages of the prior art, an objective of the present application is to provide a semiconductor device, including:
a substrate;
a buffer layer on a side of the substrate;
a first semiconductor layer on a side of the buffer layer away from the substrate; a second semiconductor layer on a side of the first semiconductor layer and the buffer layer away from the substrate, the second semiconductor layer having a lower carrier mobility than the first semiconductor layer, and an orthographic projection of the first semiconductor layer on the substrate being within an orthographic projection of the second semiconductor layer on the substrate;
a first insulation layer on a side of the second semiconductor layer away from the substrate; and a first electrode on a side of the first insulation layer away from the substrate, the orthographic projection of the first semiconductor layer on the substrate being within an orthographic projection of the first electrode on the substrate.

The present application further provides a method for manufacturing a semiconductor device, the method including:
providing a substrate;
forming a buffer layer and a first semiconductor layer on a side of the substrate; forming a second semiconductor layer on a side of the first semiconductor layer and the buffer layer away from the substrate, the second semiconductor layer having a lower carrier mobility than the first semiconductor layer, and an orthographic projection of the first semiconductor layer on the substrate being within an orthographic projection of the second semiconductor layer on the substrate;
forming a first insulation layer on a side of the second semiconductor layer away from the substrate;
forming a first electrode on a side of the first insulation layer away from the substrate, the orthographic projection of the first semiconductor layer on the substrate being within an orthographic projection of the first electrode on the substrate; and
performing ion implantation on the second semiconductor layer from a side of the first electrode away from the substrate.

The present application further provides an electronic device, including a semiconductor device provided in the present application.

The present application has the following beneficial effects with respect to the prior art.

The present application provides a semiconductor device, a method for manufacturing a semiconductor device, and an electronic device. Two semiconductor layers having different carrier mobilities are provided, the semiconductor layer having a lower carrier mobility covers the semiconductor layer having a higher carrier mobility, and the semiconductor layer having a higher carrier mobility is located within the coverage area of a first electrode, such that when ion implantation is performed on the semiconductor layer to form a source contact region and a drain contact region, the implanted ions are mainly concentrated in a region having a lower carrier mobility, which can reduce the diffusion distance of the irons and ensure an effective channel length of the semiconductor device.

### BRIEF DESCRIPTION OF THE DRAWINGS

FIG. 1 is schematic diagram of a structure of a semiconductor device according to the related art;

FIG. 2 is a schematic diagram showing ion implantation of a semiconductor device according to the related art;

FIG. 3 is a first schematic diagram of a structure of a display panel according to an embodiment of the present application;

FIG. 4 is a second schematic diagram of a structure of a display panel according to an embodiment of the present application;

FIG. 5 is a third schematic diagram of a structure of a display panel according to an embodiment of the present application;

FIG. 6 is a fourth schematic diagram of a structure of a display panel according to an embodiment of the present application;

FIG. 7 is a fifth schematic diagram of a structure of a display panel according to an embodiment of the present application;

FIG. 8 is a six schematic diagram of a structure of a display panel according to an embodiment of the present application;

FIG. 9 is a seven schematic diagram of a structure of a display panel according to an embodiment of the present application;

FIG. 10 is an eighth schematic diagram of a structure of a display panel according to an embodiment of the present application;

FIG. 11 is a ninth schematic diagram of a structure of a display panel according to an embodiment of the present application;

FIG. 12 is a tenth schematic diagram of a structure of a display panel according to an embodiment of the present application;

FIG. 13 is an eleventh schematic diagram of a structure of a display panel according to an embodiment of the present application;

FIG. 14 is a schematic flowchart of steps of a method for manufacturing a display panel according to an embodiment of the present application; and

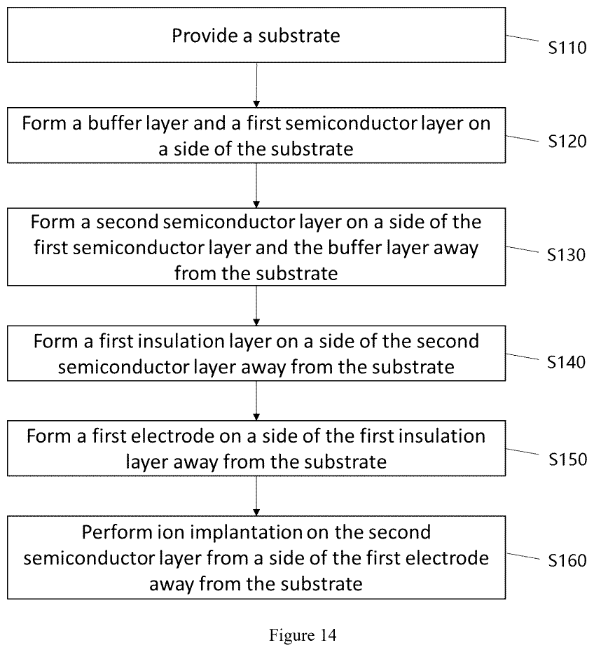

FIG. 15 is a schematic diagram of a process for manufacturing a display panel according to an embodiment of the present application.

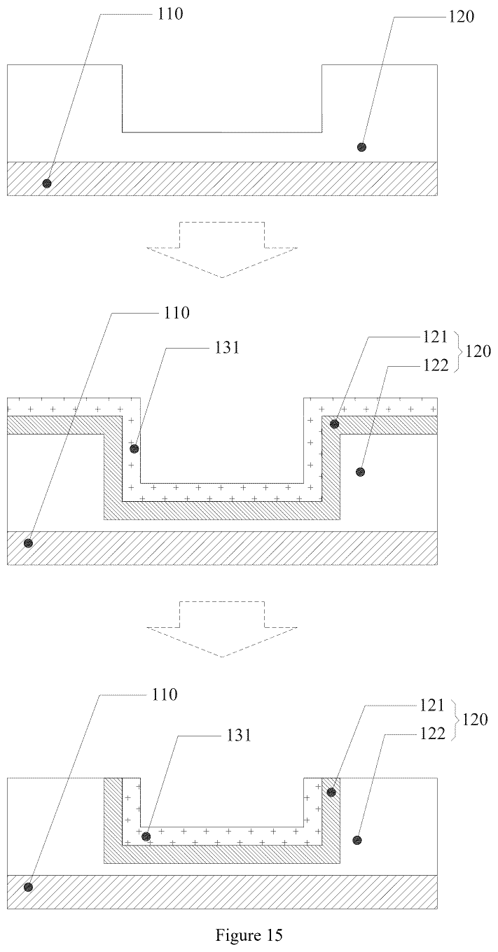

List of reference signs: 110-substrate; 120-buffer layer; 121-first buffer layer; 122-second buffer layer; 1201-trench; 1202-projection; 131-first semiconductor layer; 132-second semiconductor layer; 133-third semiconductor layer; 1321-first region; 1322-second region; 1323-third region; 140-first insulation layer; 150-first electrode; 160-second insulation layer; 170-second electrode; 180-third electrode.

### DETAILED DESCRIPTION OF EMBODIMENTS

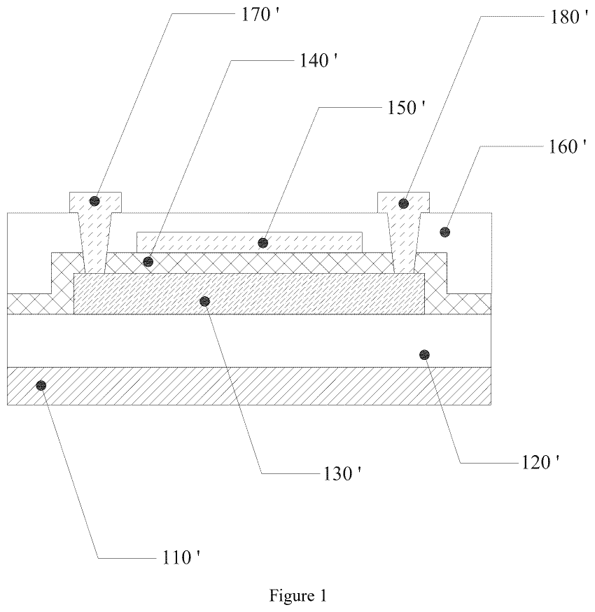

Referring to FIG. 1, FIG. 1 is a schematic diagram of a structure of a semiconductor device according to the related art, and such a semiconductor device includes a substrate 110′, a buffer layer 120′ on a side of the substrate 110′, a semiconductor layer 130′ on a side of the buffer layer 120′ away from the substrate 110′, a first insulation layer 140′ on a side of the semiconductor layer 130′ away from the substrate 110′, a gate 150′ on a side of the first insulation layer 140′ away from the substrate 110′, a second insulation layer 160′ on a side of the gate 150′ layer away from the substrate 110′, and a source 170′ and a drain 180′ electrically connected to the semiconductor layer 130′ from a side of the second insulation layer 160′ away from the substrate 110′.

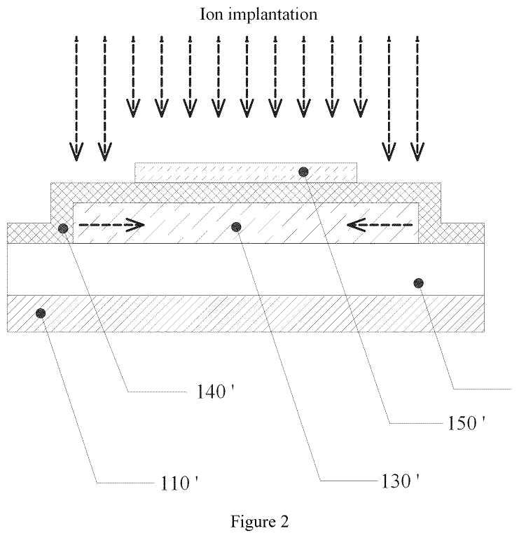

Referring to FIG. 2, during manufacturing of the semiconductor layer device as described above, after the gate 150′ is formed, the gate 150′ acts as a mask, and ion implantation is performed from a side of the gate 150′, so as to form a source contact region and a drain contact region at two ends of the semiconductor layer 130′. However, after the semiconductor layer 130′ has been subjected to ion implantation, the implanted ions diffuse in the semiconductor layer 130′, resulting in an expansion of a conductive region of the semiconductor layer 130′, and reducing an effective channel length of the semiconductor device. In particular, in some semiconductor devices, the semiconductor layer 130′ having a higher carrier mobility is used in order to reduce the size of the semiconductor device, and the ions diffuse to a greater extent in the semiconductor layer 130′ after implantation, increasing the risk of abnormal conduction of the semiconductor device.

In view of this, an embodiment of the present application provides a solution in which a diffusion distance of the implanted ions in the semiconductor layer can be suppressed, and the effective channel length of a device can be ensured. The solution provided in this embodiment is described in detail below.

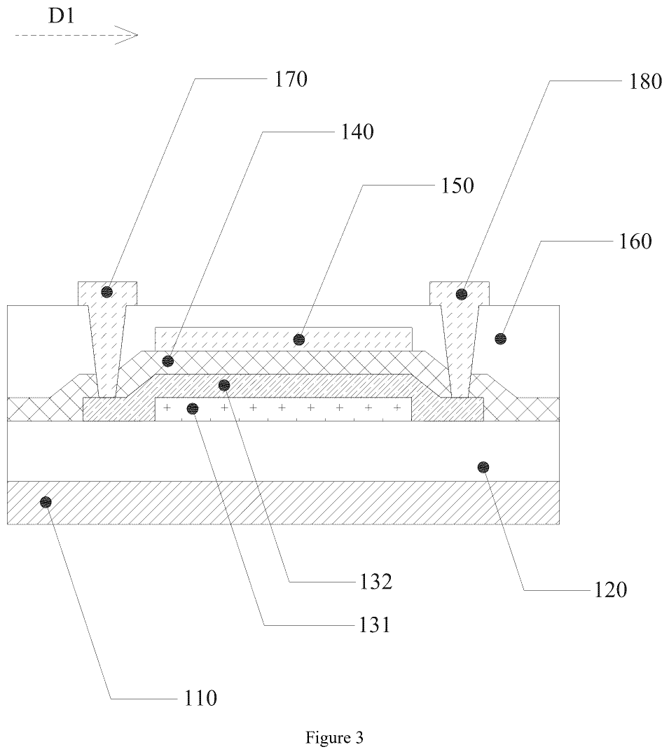

Referring to FIG. 3, FIG. 3 is a schematic diagram of a structure of a semiconductor device according to an embodiment of the present application, and the semiconductor device may include a substrate 110, a buffer layer 120, a first semiconductor layer 131, a second semiconductor layer 132, a first insulation layer 140, and a first electrode 150.

In this embodiment, the substrate 110 may be coated with polyimide (PI). For example, the substrate 110 may be coated with two layers of polyimide, in which the first layer of polyimide may have a thickness of 7.5 to 9.5 microns, e.g., 8.3 microns, 8.5 microns, or 8.7 microns, and the second layer of polyimide may have a thickness of 6.5 microns to 8.5 microns, e.g., 7.3 microns, 7.5 microns, or 7.7 microns.

The buffer layer 120 is located on a side of the substrate 110. In this embodiment, a material of the buffer layer 120 may include an inorganic oxide or a metal oxide.

The first semiconductor layer 131 is located on a side of the buffer layer 120 away from the substrate 110, and the second semiconductor layer 132 is located on a side of the first semiconductor layer 131 away from the substrate 110. In this embodiment, the second semiconductor layer 132 has a lower carrier mobility than the first semiconductor layer 131.

An orthographic projection of the first semiconductor layer 131 on the substrate 110 is within an orthographic projection of the second semiconductor layer 132 on the substrate 110.

The first insulation layer 140 is located on a side of the second semiconductor layer 132 away from the substrate 110. In this embodiment, the first insulation layer 140 may be a gate insulation layer (GI).

The first electrode 150 is located on a side of the first insulation layer 140 away from the substrate 110, and in this embodiment, the first electrode 150 may be a gate. The orthographic projection of the first semiconductor layer 131 on the substrate 110 is within an orthographic projection of the first electrode 150 on the substrate 110.

In this way, in this embodiment, when ion implantation is performed on the semiconductor layer after the first electrode 150 is formed, the first electrode 150 may shield the first semiconductor layer 131 and a first region 1321 of the second semiconductor layer 132, such that the implanted ions are mainly concentrated in the second semiconductor layer 132 having a lower carrier mobility, which can reduce the diffusion distance of the implanted ions, and ensure the effective channel length of the semiconductor device.

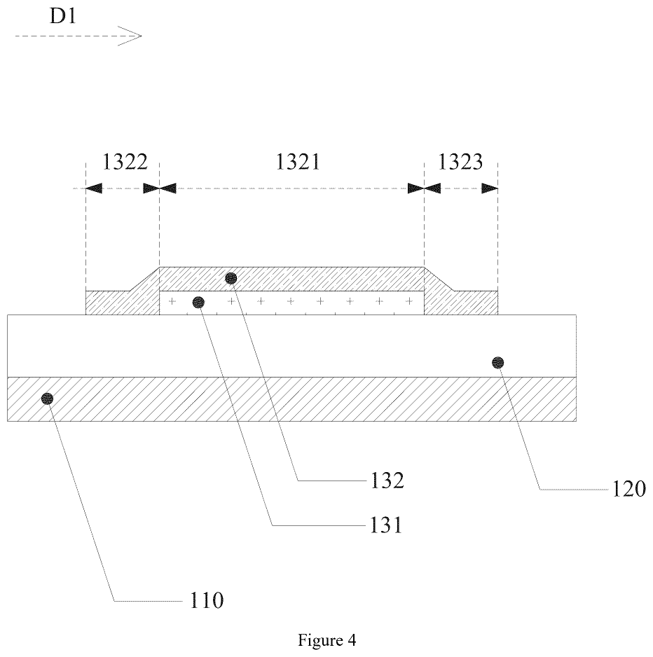

In some possible implementations, referring to FIG. 4, the second semiconductor layer 132 may include a first region 1321, a second region 1322, and a third region 1323. In a first direction D1 parallel to the substrate 110, an orthographic projection of the first region 1321 on the substrate 110 is between orthographic projections of the second region 1322 and the third region 1323 on the substrate 110, the orthographic projection of the first region 1321 on the substrate 110 coincides with the orthographic projection of the first semiconductor layer 131 on the substrate 110, and the orthographic projections of the second region 1322 and the third region 1323 on the substrate 110 do not coincide with the orthographic projection of the first semiconductor layer 131 on the substrate 110.

That is, in this embodiment, the second semiconductor layer 132 can cover the first semiconductor layer 131, and two ends of the second semiconductor layer 132 extend beyond the first semiconductor layer 131 in the first direction D1. In this way, in a subsequent ion implantation process, the ion implantation may be performed only on the second region 1322 and the third region 1323 of the second semiconductor layer 132 that extend beyond the first semiconductor layer 131, thereby preventing the implanted ions from lateral diffusion in the first semiconductor layer 131 having a higher mobility and affecting the channel length.

Further, in some possible implementations, referring again to FIG. 3, the semiconductor device further includes a second insulation layer 160, a second electrode 170, and a third electrode 180.

The second insulation layer 160 is located on a side of the first electrode 150 and the first insulation layer 140 away from the substrate 110. In this embodiment, the second insulation layer 160 may include a capacitance insulation layer (CI).

The second electrode 170 and the third electrode 180 may be located on a side of the second insulation layer 160 away from the substrate 110 and electrically connected to the second region 1322 and the third region 1323, respectively, via through holes extending through the second insulation layer 160 and the first insulation layer 140. In this embodiment, that second electrode 170 and the third electrode 180 may be a drain and a source, respectively.

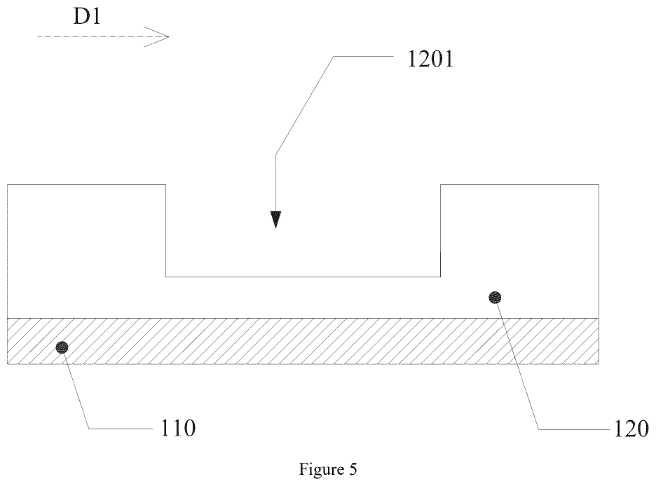

In some possible implementations, referring to FIG. 5, the buffer layer 120 may include a trench 1201 recessed from a side away from the substrate 110 toward a side close to the substrate 110.

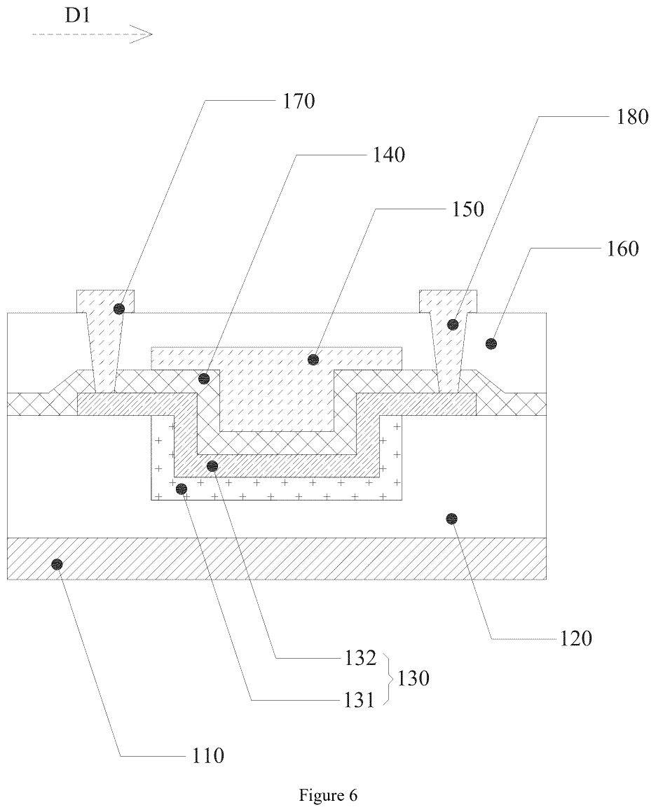

Referring to FIG. 6, the first semiconductor layer 131 extends from a bottom of the trench 1201 to be attached to two opposite side walls of the trench 1201 in the first direction D1.

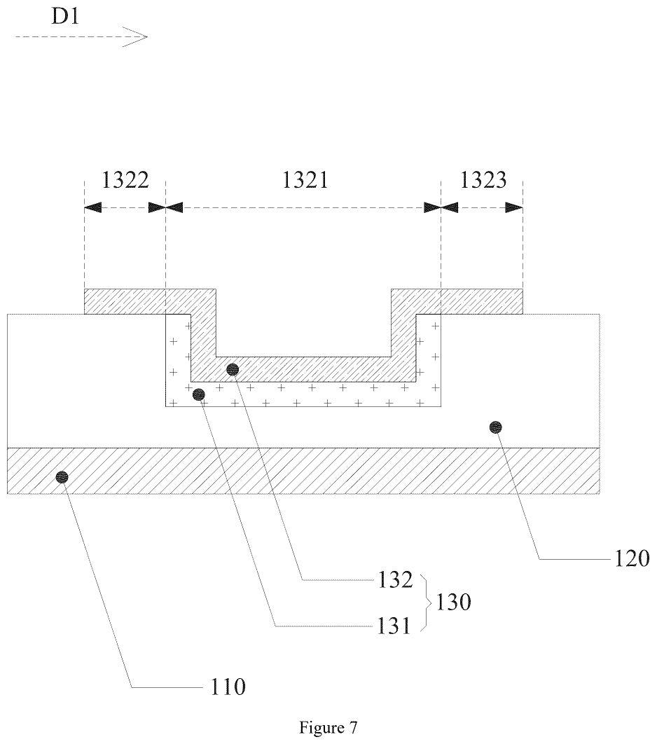

The second semiconductor layer 132 extends in the first direction D1 from one side outside the trench 1201 to the other side outside the trench 1201 across the first semiconductor layer 131 located in the trench 1201. Referring to FIG. 7, in the first direction D1, the second region 1322 and the third region 1323 of the second semiconductor layer 132 may be located on two sides outside the trench 1201.

In this way, at least a portion of a channel region formed by the first semiconductor layer 131 and the second semiconductor layer 132 may extend along the side walls of the trench 1201 in a thickness direction of the buffer layer 120, which can increase the effective channel length of a semiconductor device without increasing the size of the semiconductor device in the first direction D1, thereby increasing the pixels per inch (PPI) of the display panel.

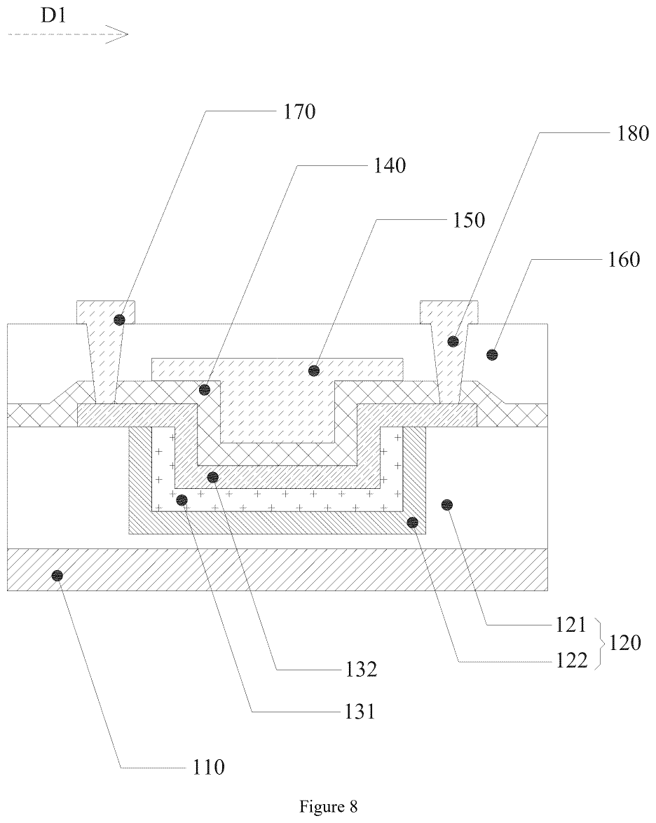

In some possible implementations, referring to FIG. 8, the buffer layer 120 includes a first buffer layer 121 and a second buffer layer 122, the second buffer layer 122 being located between the first buffer layer 121 and the first semiconductor layer 131. The second buffer layer 122 has a greater density than the first buffer layer 121. In this way, the dense second buffer layer 122 is provided between the first buffer layer 121 and the first semiconductor layer 131, and the second buffer layer 122 can prevent back-side impurities, such as hydrogen ions in other film layers on a side of the substrate 110, from affecting the first semiconductor layer 131 and the second semiconductor layer 132, thereby ensuring the operational performance of the semiconductor device.

Optionally, in this embodiment, the second buffer layer 122 has a density of 5 g/cm³ to 7 g/cm³. For example, the density may be 5.5 g/cm³, 6 g/cm³ or 6.5 g/cm³.

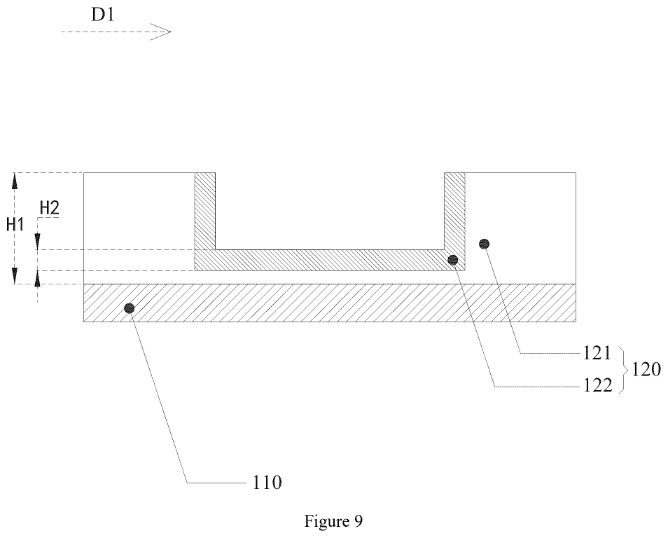

Further, referring to FIG. 9, the first buffer layer 121 includes a recess recessed from a side away from the substrate 110 toward a side close to the substrate 110, and the second buffer layer 122 covers a bottom and side walls of the recess to form the trench 1201.

For example, in this embodiment, since the first buffer layer 121 has a smaller density and a larger thickness, a recess may be formed in the first buffer layer 121 by means of etching first, and the second buffer layer 122 having a greater density and a smaller thickness and attached to the bottom and side walls of the recess is then formed in the recess by means of deposition.

Optionally, the first buffer layer 121 may be formed by means of plasma enhanced chemical vapor deposition (PECVD), and the second buffer layer 122 is then formed by means of atomic layer deposition (ALD) with a lower film formation rate. It should be noted that the formation of the first buffer layer 121 and the second buffer layer 122 as described above is merely an optional way provided for this embodiment, and in this embodiment, the first buffer layer 121 and the second buffer layer 122 may be formed in other ways, for example, both the first buffer layer and the second buffer layer may be formed by means of plasma enhanced chemical vapor deposition, which is not specifically limited here.

Optionally, referring to FIG. 9, the first buffer layer 121 has a thickness H1 in a range from 4000 Å to 50000 Å in an area outside the recess, for example, the thickness may be 5000 Å, 25000 Å, or 40000 Å; and the second buffer layer 122 has a thickness H2 in a range from 10 Å to 100 Å, for example, the thickness may be 30 Å, 50 Å, or 80 Å.

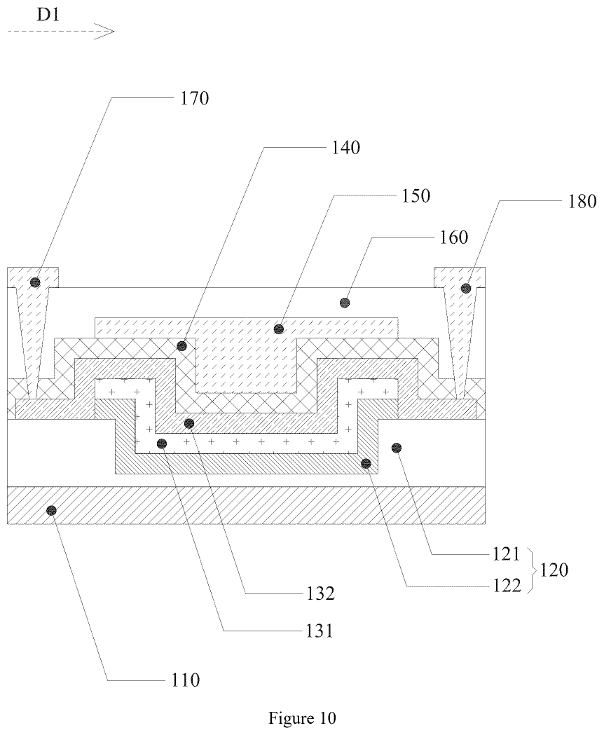

In some possible implementations, referring to FIG. 10, portions of the second buffer layer 122 and the first semiconductor layer 131 may extend from within the recess of the first buffer layer 121 to outside the recess.

In some other possible implementations, referring again to FIG. 8, an orthographic projection of the second buffer layer 122 on the substrate 110 is within an orthographic projection of the recess on the substrate 110, and the orthographic projection of the first semiconductor layer 131 on the substrate 110 is within the orthographic projection of the second buffer layer 122 on the substrate 110. That is, both the second buffer layer 122 and the first semiconductor layer 131 are located only in the recess of the first buffer layer 121. Preferably, portions of the second buffer layer 122 and the first semiconductor layer 131 attached to the side walls of the recess are flush with an opening of the recess at a side away from the substrate 110. In this way, the second buffer layer 122 and the first semiconductor layer 131 are full-layer evaporated and then etched together to form the topography shown in FIG. 8, thereby reducing manufacturing processes for the semiconductor device and improving the manufacturing efficiency.

In some possible implementations, a material of the first semiconductor layer 131 includes indium zinc oxide doped with metal, where the atomic ratio of indium to zinc ranges from 2:1 to 5:1, for example, the atomic ratio of indium to zinc may be 2.5:1, 3.5:1, or 4.5:1. The first semiconductor layer 131 may be formed by means of atomic layer deposition (ALD) or physical vapor deposition (PVD).

A material of the second semiconductor layer 132 includes indium zinc oxide doped with metal, where the atomic ratio of indium to zinc is less than 2:1. For example, the atomic ratio of indium to zinc may be 1.5:1, 1:1 or 1:2. The second semiconductor layer 132 may be formed by means of atomic layer deposition or physical vapor deposition.

Optionally, the metal doped in the first semiconductor layer 131 includes at least one of gallium, tin, niobium and tantalum; and the metal doped in the second semiconductor layer 132 includes at least one of gallium and tin.

Optionally, the first semiconductor layer 131 has a thickness in a range from 50 Å to 500 Å, for example, the first semiconductor layer 131 may have a thickness of 100 Å, 250 Å, or 400 Å; and the second semiconductor layer 132 has a thickness in a range from 50 Å to 500 Å, for example, the second semiconductor layer 132 may have a thickness of 100 Å, 250 Å, or 400 Å.

In some possible implementations, a material of the first buffer layer 121 may include a stacked structure of silicon oxide (SiOx) and amorphous silicon (a-Si).

A material of the second buffer layer 122 may include inorganic oxides, including silicon-based oxides. For example, the material of the second buffer layer 122 may include silicon oxide (SiOx), which forms an insulation layer having a high compactness and a low hydrogen content (e.g., the hydrogen content is less than 5%) by means of a high temperature process (≥250° C.).

The material of the second buffer layer 122 may include a metal oxide, such as aluminum trioxide (Al2O3) or indium zinc oxide doped with metal, where the atomic ratio of indium to zinc is less than 2:1, for example, the atomic ratio of indium to zinc may be 1.5:1, 1:1 or 1:2. The metal doped in the second buffer layer 122 includes gallium or tin.

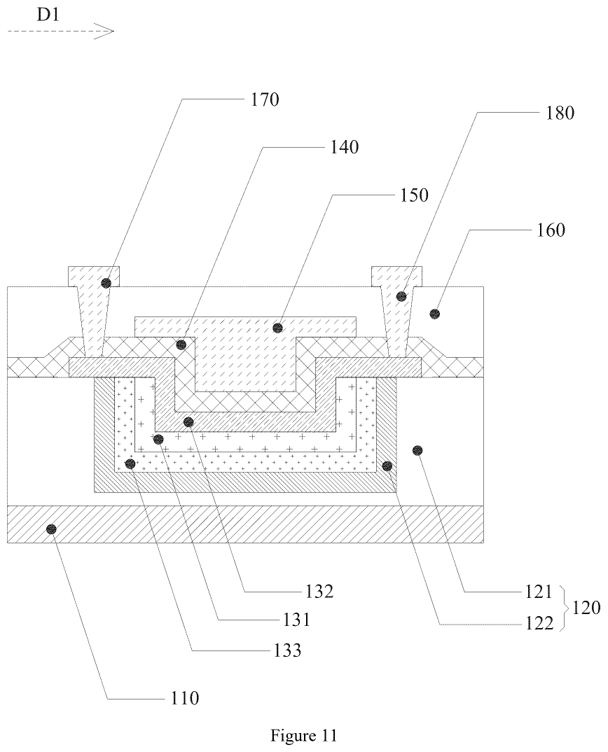

In some possible implementations, referring to FIG. 11, the semiconductor device may further include a third semiconductor layer 133.

The third semiconductor layer 133 is located between the first semiconductor layer 131 and the buffer layer 120, and the third semiconductor layer 133 has a smaller carrier mobility than the first semiconductor layer 131.

A material of the third semiconductor layer 133 includes indium zinc oxide doped with metal, where the atomic ratio of indium to zinc is less than 2:1, for example, the atomic ratio of indium to zinc may be 1.5:1, 1:1 or 1:2. The third semiconductor layer 133 may be formed by means of atomic layer deposition or physical vapor deposition. The third semiconductor layer 133 has a thickness in a range from 50 Å to 150 Å, for example, the third semiconductor layer 133 may have a thickness of 70 Å, 100 Å, or 130 Å.

In this way, the third semiconductor layer 133 can improve the ability of the semiconductor device for blocking the back-side impurities (e.g., hydrogen ions) from the side of the substrate 110. In addition, by controlling the manufacturing process, a plurality of semiconductor layers can be combined into a plurality of conductive channels to improve the overall carrier mobility of the semiconductor device.

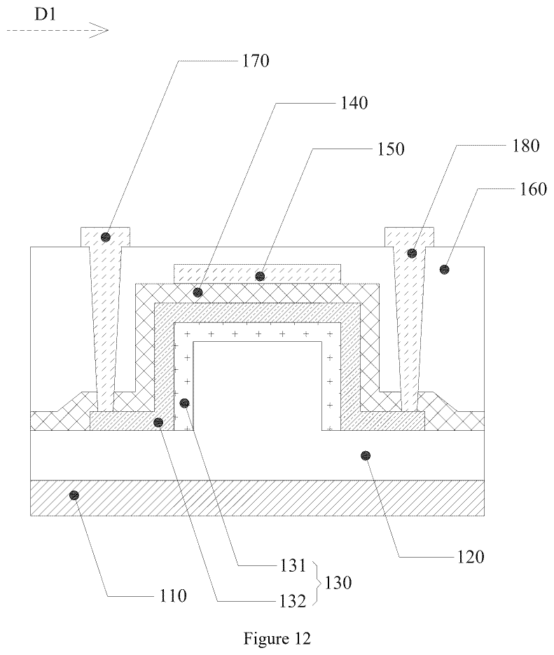

In some other possible implementations, referring to FIG. 12, the buffer layer 120 may include a projection 1202 protruding from a side close to the substrate 110 toward a side away from the substrate 110.

The first semiconductor layer 131 is attached to a side of the projection 1202 away from the substrate 110 and to two opposite side walls of the projection 1202 in the first direction D1. The second semiconductor layer 132 extends in the first direction D1 from one side of the projection 1202 to the other side of the projection across the first semiconductor layer 131 attached to the projection 1202.

In this way, at least a portion of a channel region formed by the first semiconductor layer 131 and the second semiconductor layer 132 may extend along the side walls of the projection 1202 in a thickness direction of the buffer layer 120, which can increase the effective channel length of a semiconductor device without increasing the size of the semiconductor device in the first direction D1, thereby increasing the pixels per inch (PPI) of the display panel.

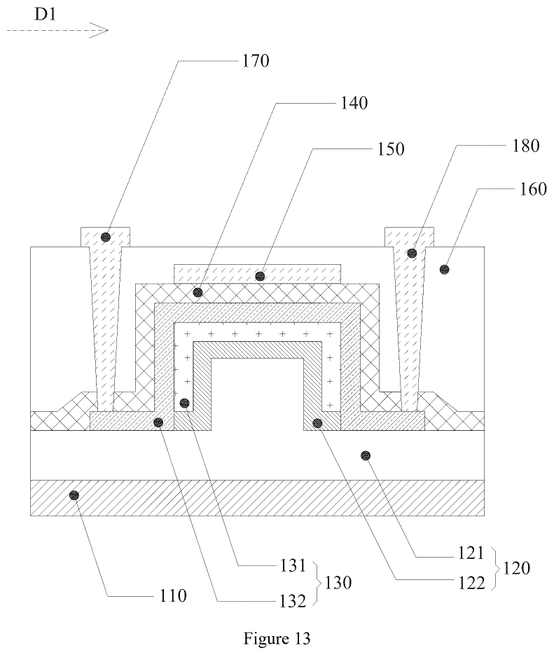

Further, referring to FIG. 13, the buffer layer 120 includes a first buffer layer 121 and a second buffer layer 122, the second buffer layer 122 being located between the first buffer layer 121 and the first semiconductor layer 131. The second buffer layer 122 has a greater density than the first buffer layer 121. In this way, the dense second buffer layer 122 is provided between the first buffer layer 121 and the first semiconductor layer 131, and the second buffer layer 122 can prevent back-side impurities, such as hydrogen ions in other film layers on a side of the substrate 110, from affecting the first semiconductor layer 131 and the second semiconductor layer 132, thereby ensuring the operational performance of the semiconductor device.

Optionally, in this embodiment, the second buffer layer 122 has a density of 5 g/cm³ to 7 g/cm³. For example, the density may be 5.5 g/cm³, 6 g/cm³ or 6.5 g/cm³.

Further, referring again to FIG. 13, the first buffer layer 121 includes a protrusion protruding from a side close to the substrate 110 toward a side away from the substrate 110, and the second buffer layer 122 covers a top and side walls of the protrusion to form the projection 1202.

Optionally, the first buffer layer 121 has a thickness in a range from 4000 Å to 50000 Å in an area outside the protrusion, for example, the thickness may be 5000 Å, 25000 Å, or 40000 Å; and the second buffer layer 122 has a thickness in a range from 10 Å to 100 Å, for example, the thickness may be 30 Å, 50 Å, or 80 Å.

In some other possible implementations, referring again to FIG. 13, an orthographic projection of the protrusion on the substrate 110 is within an orthographic projection of the second buffer layer 122 on the substrate 110, and the orthographic projection of the second buffer layer 122 on the substrate 110 is within an orthographic projection of the first semiconductor layer 131 on the substrate 110. That is, both the second buffer layer 122 and the first semiconductor layer 131 are located outside the protrusion of the first buffer layer 121.

An embodiment of the present application further provides a method for manufacturing a semiconductor device. Referring to FIG. 12, the method may include the following steps.

In step S110, a substrate 110 is provided.

In step S120, a buffer layer 120 and a first semiconductor layer 131 are formed on a side of the substrate 110.

In step S130, a second semiconductor layer 132 is formed on a side of the first semiconductor layer 131 and the buffer layer 120 away from the substrate 110.

An orthographic projection of the first semiconductor layer 131 on the substrate 110 is within an orthographic projection of the second semiconductor layer 132 on the substrate 110. For example, the second semiconductor layer 132 has a lower carrier mobility than the first semiconductor layer 131. The second semiconductor layer 132 includes a first region 1321, a second region 1322, and a third region 1323. In a first direction D1 parallel to the substrate 110, an orthographic projection of the first region 1321 on the substrate 110 is between orthographic projections of the second region 1322 and the third region 1323 on the substrate 110. The orthographic projection of the first region 1321 on the substrate 110 coincides with the orthographic projection of the first semiconductor layer 131 on the substrate 110, and the orthographic projections of the second region 1322 and the third region 1323 on the substrate 110 do not coincide with the orthographic projection of the first semiconductor layer 131 on the substrate 110.

In step S140, a first insulation layer 140 is formed on a side of the second semiconductor layer 132 away from the substrate 110.

In step S150, a first electrode 150 is formed on a side of the first insulation layer 140 away from the substrate 110. The orthographic projection of the first semiconductor layer 131 on the substrate 110 is within an orthographic projection of the first electrode 150 on the substrate 110.

In step S160, ion implantation is performed on the second semiconductor layer 132 from a side of the first electrode 150 away from the substrate 110.

In some possible implementations, the buffer layer 120 may include a trench 1201 recessed from a side away from the substrate 110 toward a side close to the substrate 110. The first semiconductor layer 131 extends from a bottom of the trench 1201 to be attached to two opposite side walls of the trench 1201 in the first direction D1. The second semiconductor layer 132 extends in the first direction D1 from one side of the trench 1201 to the other side of the trench 1201 across the first semiconductor layer 131 located in the trench 1201. Referring to FIG. 7, in the first direction D1, the second region 1322 and the third region 1323 of the second semiconductor layer 132 may be located on two sides outside the trench 1201.

Further, the buffer layer 120 includes a first buffer layer 121 and a second buffer layer 122. Specifically, the following sub-steps may be included in step S120.

In step S121, the first buffer layer 121 is formed on the substrate 110, and a recess recessed from a side away from the substrate 110 toward a side close to the substrate 110 is formed on the first buffer layer 121.

In step S122, the second buffer layer 122 and the first semiconductor layer 131 are sequentially formed by means of deposition from a side of the first buffer layer 121 away from the substrate 110, and the second buffer layer 122 and the first semiconductor layer 131 are patterned and etched to remove the second buffer layer 122 and the first semiconductor layer 131 outside the recess.

In some other possible implementations, the buffer layer 120 may include a projection 1202 protruding from a side close to the substrate 110 toward a side away from the substrate 110.

The first semiconductor layer 131 is attached to a side of the projection 1202 away from the substrate 110 and to two opposite side walls of the projection 1202 in the first direction D1. The second semiconductor layer 132 extends in the first direction D1 from one side of the projection 1202 to the other side of the projection across the first semiconductor layer 131 attached to the projection 1202.

Further, the buffer layer 120 includes a first buffer layer 121 and a second buffer layer 122. Specifically, the following sub-steps may be included in step S120.

In step S121, the first buffer layer 121 is formed on the substrate 110, and the first buffer layer 121 is etched to form a protrusion protruding from a side close to the substrate 110 toward a side away from the substrate 110.

In step S122, the second buffer layer 122 covering the protrusion and the first semiconductor layer 131 covering the second buffer layer 122 are sequentially formed by means of deposition from a side of the first buffer layer 121 away from the substrate 110.

An embodiment of the present application further provides an electronic device, including a semiconductor device provided in the present application.

Optionally, the electronic device may include a device having a display function, e.g., a display panel, a mobile phone, a tablet, a smart wearable device, a TV, a laptop, a display, etc.

In summary, the present application provides a semiconductor device, a method for manufacturing a semiconductor device, and an electronic device. Two semiconductor layers having different carrier mobilities are provided, the semiconductor layer having a lower carrier mobility covers the semiconductor layer having a higher carrier mobility, and the semiconductor layer having a higher carrier mobility is located within the coverage area of a first electrode, such that when ion implantation is performed on the semiconductor layer to form a source contact region and a drain contact region, the implanted ions are mainly concentrated in a region having a lower carrier mobility, which can reduce the diffusion distance of the irons and ensure an effective channel length of the semiconductor device.

The technical features of the above embodiments may be combined arbitrarily. For the purpose of simplicity in description, all the possible combinations of the technical features in the above embodiments are not described. However, as long as there is no contradiction in the combinations of these technical features, they shall all fall within the scope of the specification.

The above embodiments merely represent several implementations of the present invention, giving specifics and details thereof, but should not be understood as limiting the scope of the present patent of invention thereby. It should be noted that various variations and improvements may also be made by those of ordinary skill in the art without departing from the spirit of the present invention and shall fall within the scope of protection of the present invention. Therefore, the scope of protection of the present patent of invention shall be in accordance with the appended claims.

What is claimed is:

1. A semiconductor device, comprising:
a substrate;
a buffer layer on a side of the substrate;
a first semiconductor layer on a side of the buffer layer away from the substrate;
a second semiconductor layer on a side of the first semiconductor layer and the buffer layer away from the substrate, the second semiconductor layer having a lower carrier mobility than the first semiconductor layer, and an orthographic projection of the first semiconductor layer on the substrate being within an orthographic projection of the second semiconductor layer on the substrate;
a first insulation layer on a side of the second semiconductor layer away from the substrate; and
a first electrode on a side of the first insulation layer away from the substrate, the orthographic projection of the first semiconductor layer on the substrate being within an orthographic projection of the first electrode on the substrate.

2. The semiconductor device according to claim 1, wherein the second semiconductor layer comprises a first region, a second region, and a third region, in a first direction parallel to the substrate, an orthographic projection of the first region on the substrate being between orthographic projections of the second region and the third region on the substrate; and the orthographic projection of the first region on the substrate coinciding with the orthographic projection of the first semiconductor layer on the substrate.

3. The semiconductor device according to claim 2, wherein the buffer layer comprises a trench recessed from a side away from the substrate toward a side close to the substrate;
the first semiconductor layer extends from a bottom of the trench to be attached to two opposite side walls of the trench in the first direction; and
the second semiconductor layer extends in the first direction from one side outside the trench to the other side outside the trench across the first semiconductor layer located in the trench.

4. The semiconductor device according to claim 3, wherein the buffer layer comprises a first buffer layer and a second buffer layer located between the first buffer layer and the first semiconductor layer, and wherein the second buffer layer has a greater density than the first buffer layer.

5. The semiconductor device according to claim 4, wherein the second buffer layer has a density of 5 g/cm³ to 7 g/cm³.

6. The semiconductor device according to claim 4, wherein the first buffer layer comprises a recess recessed from a side away from the substrate toward a side close to the substrate, and the second buffer layer covers a bottom and side walls of the recess to form the trench.

7. The semiconductor device according to claim 6, wherein the first buffer layer has a thickness in a range from 4000 Å to 50000 Å in an area outside the recess, and the second buffer layer has a thickness in a range from 10 Å to 100 Å.

8. The semiconductor device according to claim 6, wherein an orthographic projection of the second buffer layer on the substrate is within an orthographic projection of the recess on the substrate, and the orthographic projection of the first semiconductor layer on the substrate is within the orthographic projection of the second buffer layer on the substrate; and
portions of the second buffer layer and the first semiconductor layer attached to the side walls of the recess are flush with an opening of the recess at a side away from the substrate.

9. The semiconductor device according to claim 2, wherein the buffer layer comprises a projection protruding from a side close to the substrate toward a side away from the substrate;
the first semiconductor layer is attached to a side of the projection away from the substrate and to two opposite side walls of the projection in the first direction; and
the second semiconductor layer extends in the first direction from one side of the projection to the other side of the projection across the first semiconductor layer attached to the projection.

10. The semiconductor device according to claim 9, wherein the buffer layer comprises a first buffer layer and a second buffer layer located between the first buffer layer and the first semiconductor layer, and wherein the second buffer layer has a greater density than the first buffer layer.

11. The semiconductor device according to claim 10, wherein the second buffer layer has a density of 5 g/cm³ to 7 g/cm³.

12. The semiconductor device according to claim 10, wherein the first buffer layer comprises a protrusion protruding from a side close to the substrate toward a side away from the substrate, and the second buffer layer covers a top and side walls of the protrusion to form the projection.

13. The semiconductor device according to claim 12, wherein the first buffer layer has a thickness in a range from 4000 Å to 50000 Å in an area outside the protrusion, and the second buffer layer has a thickness in a range from 10 Å to 100 Å.

14. The semiconductor device according to claim 12, wherein an orthographic projection of the protrusion on the substrate is within an orthographic projection of the second buffer layer on the substrate, and the orthographic projection of the second buffer layer on the substrate is within the orthographic projection of the first semiconductor layer on the substrate.

15. The semiconductor device according to claim 1, wherein a material of the first semiconductor layer comprises indium zinc oxide doped with metal, wherein the atomic ratio of indium to zinc ranges from 2:1 to 5:1; and a material of the second semiconductor layer comprises indium zinc oxide doped with metal, wherein the atomic ratio of indium to zinc is less than 2:1; and
the metal doped in the first semiconductor layer comprises at least one of gallium, tin, niobium and tantalum, and the metal doped in the second semiconductor layer comprises at least one of gallium and tin.

16. The semiconductor device according to claim 15, wherein the first semiconductor layer has a thickness in a range from 50 Å to 500 Å, and the second semiconductor layer has a thickness in a range from 50 Å to 500 Å.

17. The semiconductor device according to claim 1, further comprising:
a third semiconductor layer located between the first semiconductor layer and the buffer layer, the third semiconductor layer having a lower carrier mobility than the first semiconductor layer.

18. The semiconductor device according to claim 2, further comprising:
a second insulation layer on a side of the first electrode and the first insulation layer away from the substrate; and
a second electrode and a third electrode on a side of the second insulation layer away from the substrate, the second electrode and the third electrode being electrically connected to the second region and the third region, respectively, via through holes extending through the second insulation layer and the first insulation layer.

19. A method for manufacturing a semiconductor device, the method comprising:
providing a substrate;
forming a buffer layer and a first semiconductor layer on a side of the substrate;
forming a second semiconductor layer on a side of the first semiconductor layer and the buffer layer away from the substrate, the second semiconductor layer having a lower carrier mobility than the first semiconductor layer, and an orthographic projection of the first semiconductor layer on the substrate being within an orthographic projection of the second semiconductor layer on the substrate;
forming a first insulation layer on a side of the second semiconductor layer away from the substrate;
forming a first electrode on a side of the first insulation layer away from the substrate, the orthographic projection of the first semiconductor layer on the substrate being within an orthographic projection of the first electrode on the substrate; and
performing ion implantation on the second semiconductor layer from a side of the first electrode away from the substrate.

20. An electronic device, comprising a semiconductor device of claim 1.
